(19) United States
(12) Patent Application Publication
(10) Pub. No.: US 2026/0036620 A1
(43) Pub. Date: Feb. 5, 2026

(54) TEST DEVICE

(71) Applicant: SILICONWARE PRECISION INDUSTRIES CO., LTD., Taichung City (TW)

(72) Inventors: Tien-Yao HSU, Taichung City (TW); Yung-Ming WANG, Taichung City (TW)

(21) Appl. No.: 18/896,461

(22) Filed: Sep. 25, 2024

(30) Foreign Application Priority Data
Jul. 31, 2024 (TW) 113128544

(51) Int. Cl. G01R 31/28; G01R 1/04

(52) U.S. Cl. CPC G01R 31/2855; G01R 1/0433

(57) ABSTRACT

A test device including a test socket and a control module is provided. The test socket has a base and a cover and is used to carry an object to be tested, and the control module is integrated on the test socket and is electrically connected to the test socket and includes a control unit and a memory unit. The test device integrates a test socket and a control module to reduce the attenuation of the analog signal and increase the layout space of the circuit board.

### CROSS-REFERENCE TO RELATED APPLICATIONS

The present application is based upon and claims the right of priority to TW Patent Application No. 113128544, filed July 31, 2024, the disclosure of which is hereby incorporated by reference herein in its entirety for all purposes.

### BACKGROUND

### Technical Field

The present disclosure relates to a test device, and more particularly, to a test device for a burn-in test.

### Description of Related Art

Currently, semiconductor components (such as wafers, chips or package modules) need to undergo a burn-in test during the quality control stage before shipment. The burn-in test uses methods such as high temperature, high pressure or high humidity to conduct reliability tests such as accelerated aging or destructiveness on the semiconductor components that are expected to leave the factory, so as to detect defective semiconductor components and eliminate them.

As shown in FIG. 1, in the conventional burn-in test, a component to be tested is mainly placed in a burn-in test socket 11, and the burn-in test socket 11 and a control unit 12 and a memory unit 13 are connected to a daughter board 14. The daughter board 14 is then connected to a mother board 15 for external transmission of detection commands to the mother board 15, the daughter board 14 and the burn-in test socket 11. Meanwhile, the burn-in test socket 11 transmits the sensed analog signal to an external analog-to-digital converter (A/D converter), which converts it to a digital signal for being decoded by the control unit 12 and stored by the memory unit 13. Then, the data required for various reliability tests is returned for subsequent analysis and processing.

However, because the analog signal transmission process needs to pass through the connector, daughter board, and mother board, the analog signal is prone to attenuation or noise interference, causing distortion of the read data (such as temperature data), resulting in the risk of detection failure and others. Further, the conventional burn-in test socket, control unit and memory unit must be connected individually to the daughter board and then to the mother board. As such, not only does it cause the problem that the overall structure is too large, but it also makes the wiring of the daughter board and the mother board complicated, and also affects the layout space of the daughter board and the mother board.

Therefore, how to overcome the above problems of the prior art has become an urgent problem to be solved.

### SUMMARY

In view of the various deficiencies of the prior art, the present disclosure provides a test device for a burn-in test of an object to be tested, which comprises: a test socket including a base and a cover, and configured for carrying the object to be tested; and a control module integrated on the test socket and electrically connected to the test socket, and including a control unit and a memory unit.

In the aforementioned test device, the test socket is mounted and electrically connected to a mother board.

In the aforementioned test device, the test socket is provided with a plurality of sensors.

In the aforementioned test device, the cover changes between an open position and a closed position relative to the base.

In the aforementioned test device, the cover has a contact portion and a heat dissipation portion.

In the aforementioned test device, the control module is located on one side of the test socket.

In the aforementioned test device, the control unit and the memory unit are provided on a carrier board and are electrically connected to the carrier board.

In the aforementioned test device, the control unit is a microprocessor or a field programmable logic gate array, and the memory unit is an electronically erasable rewritable read-only memory.

In the aforementioned test device, the control module is electrically connected to a mother board via spring conductive contact pins.

In the aforementioned test device, the control unit receives a sensing signal of the test socket and sends a control signal accordingly.

In the aforementioned test device, the control unit is combined with an analog-to-digital signal conversion unit to directly convert an analog signal of the sensing signal into a digital signal.

As can be seen from the above, in the test device of the present disclosure, the test socket is embedded or integrated with the control module, and through the combination of the control unit and the memory unit, it is transmitted to the external processing equipment through the digital signal bus to reduce problems such as analog signal attenuation, noise interference and others. In addition, the test device transmits digital signals, which not only reduces the complexity and cost of the wiring of the circuit board, increases the layout space of the circuit board, but also solves the conventional problem that the overall structure is too large due to the burn-in test socket, control unit, and memory unit having to be individually connected to the daughter board and then connected to the mother board.

### BRIEF DESCRIPTION OF THE DRAWINGS

FIG. 1 is a schematic view of a configuration of a conventional burn-in test socket.

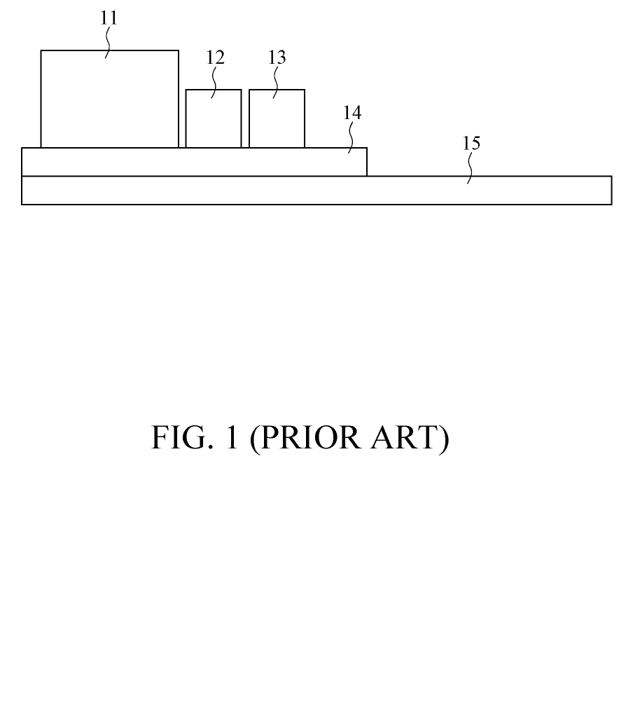

FIG. 2 is a schematic side view of a configuration of a test device according to the present disclosure.

FIG. 3 is a schematic top view of the configuration of the test device according to the present disclosure.

FIG. 4 is a schematic side view of a control module of the test device according to the present disclosure.

FIG. 5 is a schematic view of an application architecture of the test device according to the present disclosure.

### DETAILED DESCRIPTION

The following describes the embodiments of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “upper,” “a,” “one” and the like are merely used for clear explanation rather than limiting the practicable scope of the present disclosure, and thus, alterations or adjustments of the relative relationships thereof without essentially altering the technical contents should still be considered in the practicable scope of the present disclosure.

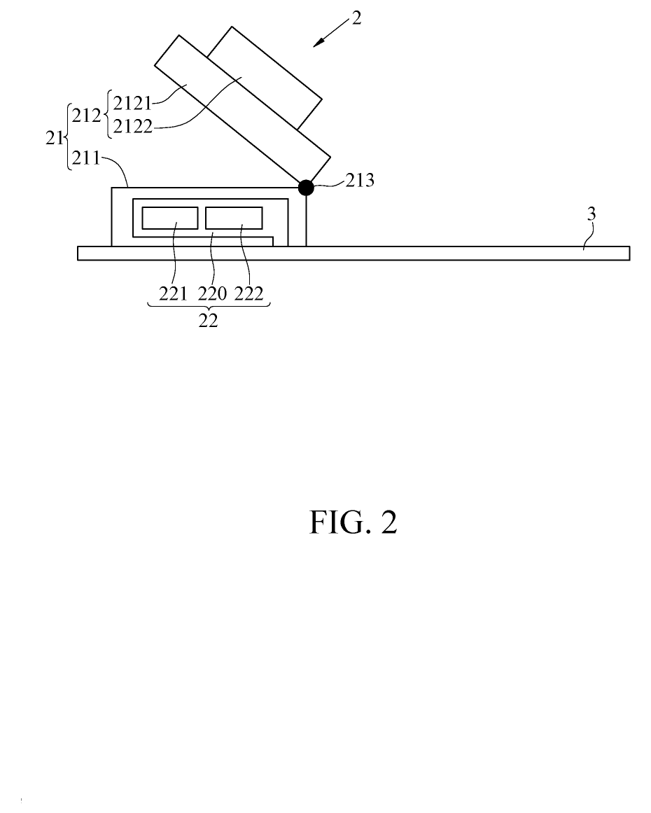

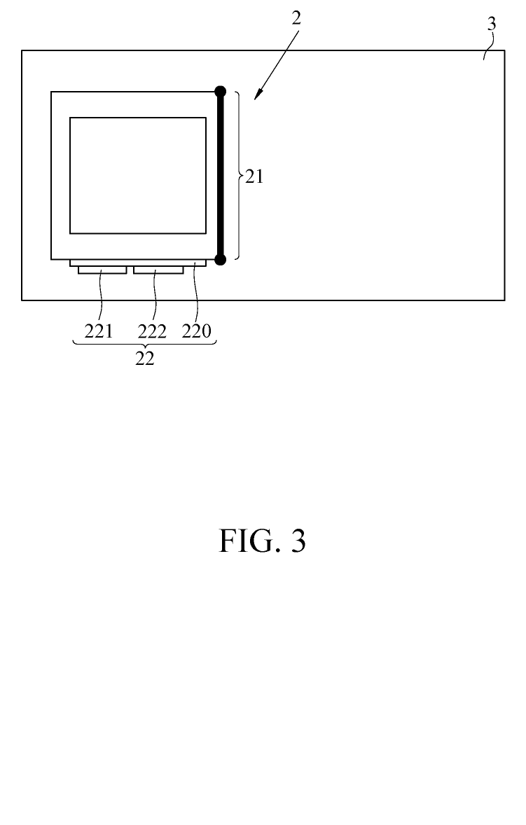

FIG. 2 and FIG. 3 are schematic side view and top view of a configuration of a test device according to the present disclosure. In one embodiment, the test device 2 is used for reliability test (such as a burn-in test) of an object to be tested (not shown), such as a wafer, a chip or a package.

The test device 2 includes a test socket 21 and a control module 22, and the test device 2 is connected and electrically connected to a circuit board (such as a mother board) 3.

The test socket 21 includes a base 211 and a cover 212, and the test socket 21 is used to carry at least one object to be tested or a plurality of objects to be tested. In addition, the test socket 21 is provided with at least one sensor or a plurality of sensors (for example, provided on the cover to sense the temperature of the object to be tested) to capture sensing signals (such as temperature signals) of the object to be tested.

The cover 212 is pivotably connected to the base 211. The bottom of the base 211 can be electrically connected to the circuit board 3 via, for example, conductive contact pins, and the base 211 has a receiving slot for placing the object to be tested. In one embodiment, the cover 212 is connected to the base 211 via a pivot structure 213. In other embodiments, the cover 212 can also be movably connected to the base 211 via other mechanisms (such as slide rails, etc.), so that the cover 212 can change between an open position and a closed position relative to the base 211, thereby exposing the object to be tested or covering the object to be tested.

The cover 212 has a contact portion 2121 and a heat dissipation portion 2122. When the cover 212 is at the closed position, the contact portion 2121 can contact the object to be tested, and the contact portion 2121 is made of thermally conductive metal. Thereby, the heat generated by the object to be tested during testing can be conducted to the heat dissipation portion 2122, such as a heat dissipation fin set, via the contact portion 2121, allowing the temperature of the object to be tested to be cooled down. The heat dissipation portion 2122 may be further connected to a fan and/or a heat pipe to facilitate cooling.

The control module 22 is integrated on the test socket 21 and is electrically connected to the test socket 21. In one embodiment, the control module 22 is located on the side of the test socket 21.

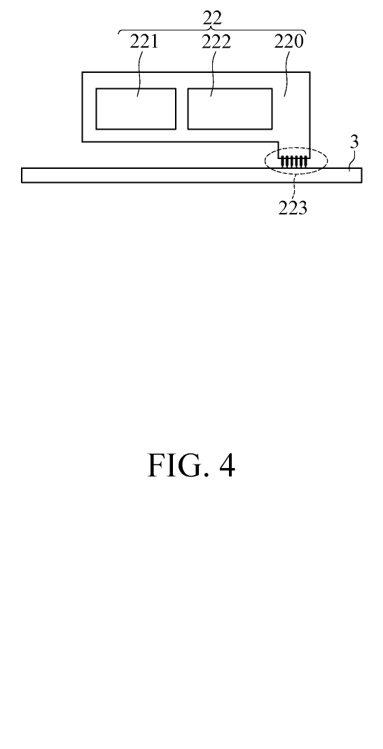

Please also refer to FIG. 4, which is a schematic side view of the control module 22 of the test device 2 according to the present disclosure, wherein the control module 22 includes a carrier board 220 and a control unit 221 and a memory unit 222 provided on the carrier board 220. The control unit 221 can be electrically connected to the test socket 21 and the memory unit 222.

The control unit 221 is, for example, a microprocessor (MCU) or a field programmable gate array (FPGA), the memory unit 222 is, for example, an electronically erasable rewritable read-only memory (EEPROM), and the control unit 221 and the memory unit 222 are electrically connected to the carrier board 220. The control module 22 (the carrier board 220) can be electrically connected to the circuit board (the mother board) 3 via, for example, spring conductive contact pins 223.

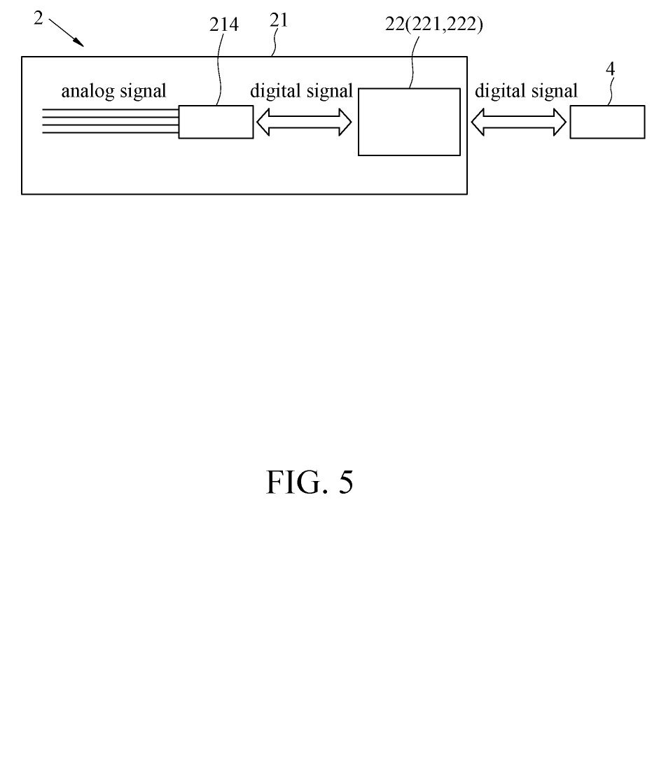

Please also refer to FIG. 5, which is a schematic view of an application architecture of the test device 2 according to the present disclosure. The control unit 221 can receive the sensing signal of the test socket 21 (such as the temperature signal of a sensor 214) and send a control signal (such as a temperature control signal) accordingly. Further, the control unit 221 can be combined with an analog-to-digital (A/D) signal conversion unit to directly convert the analog signal of the sensing signal into a digital signal, and then the digital signal can be directly transmitted to an external processing equipment (such as a computer equipment) 4. In addition, the memory unit 222 can be used to store information such as identification information and usage time of the test socket 21. Accordingly, the test device 2 integrates the test socket 21 and the control module 22 to perform analog-to-digital (A/D) signal conversion internally and transmit it via digital signals, thereby increasing the stability of subsequent signal processing and reading.

Therefore, in the test device of the present disclosure, the test socket is embedded or integrated with the control module, and through the combination of the control unit and the memory unit, it is transmitted to the external processing equipment through the digital signal bus to reduce problems such as analog signal attenuation, noise interference and others. In addition, the test device transmits digital signals, which not only reduces the complexity and cost of the wiring of the circuit board, increases the layout space of the circuit board, but also solves the conventional problem that the overall structure is too large due to the burn-in test socket, control unit, and memory unit having to be individually connected to the daughter board and then connected to the mother board.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A test device for a burn-in test of an object to be tested, comprising:
a test socket including a base and a cover, and configured for carrying the object to be tested; and
a control module integrated on the test socket and electrically connected to the test socket, and including a control unit and a memory unit.

2. The test device of claim 1, wherein the test socket is mounted on and electrically connected to a mother board.

3. The test device of claim 1, wherein the test socket is provided with a sensor.

4. The test device of claim 1, wherein the cover changes between an open position and a closed position relative to the base.

5. The test device of claim 1, wherein the cover has a contact portion and a heat dissipation portion.

6. The test device of claim 1, wherein the control module is located on one side of the test socket.

7. The test device of claim 1, wherein the control unit and the memory unit are provided on a carrier board and are electrically connected to the carrier board.

8. The test device of claim 1, wherein the control unit is a microprocessor or a field programmable logic gate array, and the memory unit is an electronically erasable rewritable read-only memory.

9. The test device of claim 1, wherein the control module is electrically connected to a mother board via spring conductive contact pins.

10. The test device of claim 1, wherein the control unit receives a sensing signal of the test socket and sends out a control signal accordingly.

11. The test device of claim 10, wherein the control unit is combined with an analog-to-digital signal conversion unit to directly convert an analog signal of the sensing signal to a digital signal.
